(19) United States
(12) Patent Application Publication
(10) Pub. No.: US 2010/0245132 A1
(43) Pub. Date: Sep. 30, 2010

(54) COMPENSATION METHOD FOR TOUCH SENSOR SYSTEM

(75) Inventors: TING-YUAN LU, Kaohsiung City (TW); WEN-LIANG LIU, Hsinchu City (TW); CHENG-MU WU, Hsinchu (TW)

Correspondence Address: WPAT, PC;INTELLECTUAL PROPERTY ATTORNEYS, 7225 BEVERLY ST., ANNANDALE, VA, 22003, US

(73) Assignee: HOLTEK SEMICONDUCTOR INC., Hsinchu (TW)

(21) Appl. No.: 12/428,874

(22) Filed: Apr. 23, 2009

(30) Foreign Application Priority Data
Mar. 25, 2009 (TW) 098109686

(51) Int. Cl. H03K 17/94

(52) U.S. Cl. 341/20

(57) ABSTRACT

A compensation method devoid of operating voltage calibration, establishing fundamental linearity calibration table and inputting, and detecting the actual operating voltage is disclosed. The compensation method comprises the steps of: a) turning off a switch in a touch sensor system; b) initializing the touch sensor system and measuring a reference frequency outputted from a oscillator in the touch sensor system; c) turning on the switch and measuring a first frequency outputted from the oscillator; and d) deducting the first frequency from the reference frequency so as to obtain a frequency difference; and e) comparing the difference with a predetermined value, and judging based upon the difference if the touch sensor system is touched by a foreign object.

### BACKGROUND OF THE INVENTION

1. Field of the invention

The present invention relates to a compensation method for a touch sensor system, more particularly, to a compensation method for a touch sensor system whose operating frequency is being affected.

2. Description of the Prior Arts

In a touch sensor system, various approaches are employed to detect a touch behavior thereof. One of them is as follows: Disposing an oscillator, which can sense the capacitance at its outside environment. While the capacitance varies, correspondingly, an oscillating frequency of the oscillator will also vary. Meanwhile, the touch sensor system can determine the touch behavior of a user based upon an oscillating frequency change. However, while an operating voltage of the touch sensor system varied, in the same manner, the oscillating frequency of the aforementioned oscillator will also be affected accordingly so as to mislead the touch sensor system to wrongly determine the user's behavior.

Suppose there exists an oscillator inside the touch sensor system. As known, the oscillator can sense the touch behavior of users. While they touch the panel, the oscillator can sense the external capacitance variation by means of lowering its outputted oscillating frequency, in such a manner, the touch sensor system can determine the touching action from the user according to the change of the oscillator frequency thereafter. The touch sensor system can function properly while the operating voltage V_{DD} remains stable and constant. However, as aforementioned, while the operating voltage is varied, the oscillator can mislead the touch sensor system. For instance, as the operating voltage is descending, the oscillating frequency of the oscillator will be dropping accordingly. Meanwhile, since the touch sensor system determined the user's touching action up to the descending of the oscillating frequency, mistakenly, the users will be treated as touching the panel system.

R.0.C. Taiwan Patent No. 1297857 discloses a linear compensation method for a touch sensor system. After the touch sensor system is calibrated according to a built rated operating voltage or setting operating voltage, at the time of installing inside an actual operating touch sensor system environment and inputting the actual operating voltage thereafter, the linear compensation method comprises a step of: renewing a linear compensation data based upon the voltage difference between the actual operating voltage and rated operating voltage/setting operating voltage so as to further ensure the touching field accuracy of actual operating voltage for a touch sensor system. However, inevitably, the method still comprise a step of calibrating the operating voltage set-up and building fundamental linearity calibrating data table and inputting/detecting the actual operating voltage.

Accordingly, in view of the above drawbacks, it is an imperative that a compensating method for a touch sensor system, particularly, a compensating method for a touch sensor system whose oscillating frequency is affected is designed so as to solve the drawbacks as the foregoing.

### SUMMARY OF THE INVENTION

In view of the disadvantages of prior art, the primary object of the present invention relates to a compensation method of a touch sensor system, devoid of setting operating voltage calibration nor establishing fundamental linearity calibration data and inputting/detecting actual operating voltage, can achieve the compensation.

The present invention relates to a compensation method for a touch sensor system, said touch sensor system comprises an oscillator connecting to a input pad outside the touch sensor system via a switch, said compensation method comprises: turning off the switch; initializing the touch sensor system and measuring a reference frequency outputted from the oscillator; turning on the switch and measuring a first frequency outputted from the oscillator; deducting the first frequency from the reference frequency so as to obtain a frequency difference; and comparing the difference with a predetermined value, and judging based upon the difference if the touch sensor system is touched by a foreign object.

The present invention also relates to a compensation method for a touch sensor system, said touch sensor system comprises an reference oscillator and a sensing oscillator, said compensation method comprising steps of: initializing said touch sensor system and measuring a reference frequency outputted from said reference oscillator; measuring a first frequency outputted from said sensing oscillator; deducting the first frequency from the reference frequency so as to obtain a frequency difference; and comparing the frequency difference with a predetermined value so as to decide if the touch sensor system is touched by a foreign object.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become readily understood from the detailed description given herein below and the accompanying drawings which are given by way of illustration only, and thus are not limitative of the present invention and wherein:

FIG. 1 is a diagram showing the relationship of the oscillating frequency vs. the operating voltage according to the oscillator in the present invention;

FIG. 2 is another diagram showing the relationship of the oscillating frequency vs. the operating voltage according to the oscillator in the present invention;

FIG. 3 is a flow chart for one of the methods disclosed in the present invention; and

FIG. 4 is another flow chart for another one of the methods disclosed in the present invention.

### DESCRIPTION OF THE EXEMPLARY EMBODIMENTS

The following descriptions are of exemplary embodiments only, and are not intended to limit the scope, applicability, or configuration of the invention in any way. Rather, the following description provides a convenient illustration for implementing exemplary embodiments of the invention. Various changes to the described embodiments may be made in the function and arrangement of the elements described. For your esteemed members of reviewing committee to further understand and recognize the fulfilled functions and structural characteristics of the invention, several exemplary embodiments cooperating with detailed description are presented as the follows.

As the aforementioned stated, while the capacitive oscillator senses the external capacitance increment, the oscillating frequency thereof will descend, and, at the time of operating voltage dropping, the same will also descend. Alternatively, it is ambiguous that the oscillating frequency falling is actually caused either by the change of the capacitance or the change of the operating voltage.

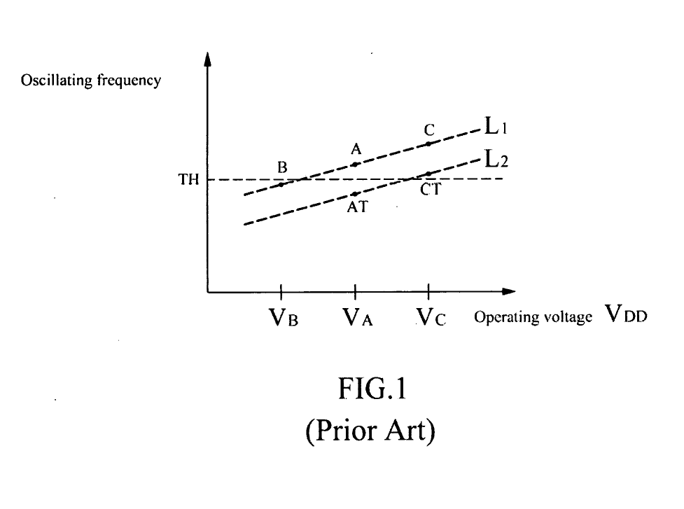

As FIG. 1 suggests, while nothing contacts the touch sensor system, the relationship of the oscillating frequency versus the operating voltage is denoted by L₁. Suppose that the operating voltage is fixed at a point such as V_{A}, and the outputted frequency by the oscillator is located at point A, then the touch sensor system uses TH as judging reference. If the oscillating frequency is lower than TH such as point B, then the system determines something already touches or approaches the system. Even though, the actual cause for that is because of the operating voltage reduction.

Furthermore, when the users touch the touch sensor system, due to the approach of the foreign object, accordingly, the induced capacitance will also be increasing. At the moment, the relationship of the oscillating frequency versus the operating voltage is denoted as L₂ in FIG. 1, where the outputted oscillating frequency for the oscillator is located at point AT. Because the oscillating frequency corresponding to AT is already lower than the boundary frequency TH for L₂, the touch sensor system determines there already exists a touch action.

However, as shown by L₂ in FIG. 1, when the user touches the touch sensor system but the operating voltage increases so as to move from the point AT to point CT, at the moment, the oscillating frequency thereof is already higher than that at TH, mistakenly, the touch sensor system will determine no touch action is taken.

Hence, to further address the issue, the determining approach for the touch sensor system is improved by using a reference frequency to eliminate an effect of the operating voltage on the touch sensor system during its variation.

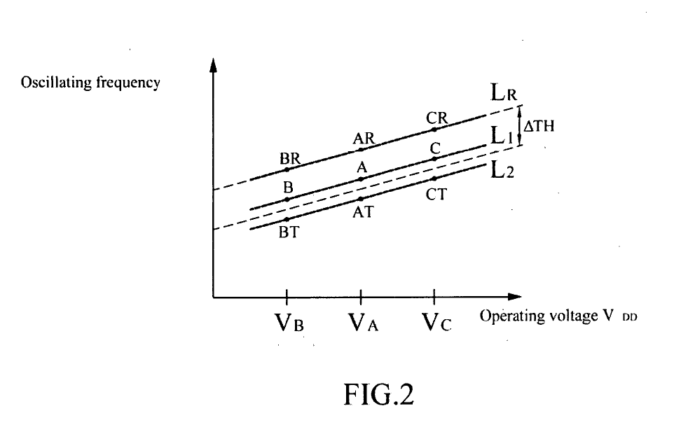

Turning up to FIG. 2 now, the relationship of the reference frequency versus the operating voltage for the reference oscillator is denoted as L_{R} in FIG. 2. The relationship of the reference frequency versus the operating voltage for the sensing oscillator is denoted as L₁ where no one is touching the touch panel. The relationship of the reference frequency versus the operating voltage for the sensing oscillator is denoted as L₂ where the user is touching the touch panel. Before the operating voltage drops, a reference frequency of the reference oscillator is denoted as AR, later on, the external sensing capacitance is detected. Before the user touches the touch sensor system, suppose the frequency of the sensing oscillator is denoted as A, then the touch sensor system uses AR-A to detect whether there exits external sensing capacitance variation. Say, at the moment, AR-A is smaller than ^{Δ} _{TH}, hence, it is treated as there is no external sensing capacitance increment. After the user touches the touch sensor system, the frequency for the sensing oscillator is denoted as AT, where the touch sensor system, in the same manner, applies AR-AT to determine if there is additional external sensing capacitance. At the moment, the value for AR-AT is larger than ^{Δ} _{TH}, hence, it is be noted that there is external sensing capacitance increase, and the touch sensor system is treated as being touched or pressed. From FIG. 2, one skilled in the art can realized, the difference between AR and AT is approximately identical to the same between CR and CT and the same between BR and BT.

The skilled artisan can also apply the sensing oscillator to serve as the reference oscillator as well. At the moment, as L_{R} and L₁ are concerned, at the time of the operating voltage change, the trend of frequency variation for L_{R}, and the same for L₁ are approximately aligned.

In case that the user does not touch the touch sensor system, if the operating voltage is dropping so as to lower the reference oscillating frequency of the oscillator from AR to BR, corresponding, the oscillating frequency for the sensing oscillator, as not touched, drops from point A to point B. In the same manner, the touch system uses the difference between BR and B, namely, BR-B, to determine the existence of the external sensing capacitance. Since BR-B is smaller than ^{Δ} _{TH}, the system determines there is no external sensing capacitance variation. In such a way, the conventional issue for mistakenly judging the user's behavior during voltage drifting for the conventional touch sensor system can be addressed. Apparently, BR-BT exceeds ^{Δ} _{TH}, hence, the system determines that there exists external capacitance incremental. In the same manner, if the operating voltage is increasing so as to enhance the reference oscillating frequency from AR to CR, at the moment, the frequency for the oscillator without being touched increases from point A to C as well. Again, the touch sensor system uses the value of CR-C as a reference to determine the existence of the external capacitance variation. Apparently, CR-C is lower than ^{Δ} _{TH}, hence, the system determines that there does not exist external capacitance variation. In the same manner, CR-CT is higher than ^{Δ} _{TH}, hence, the system determines that there exists external capacitance variation. In such a way, the conventional touch sensor system no longer suffers from the voltage drifting and the user's behavior will not be mistakenly judged at the time of operating voltage drifting.

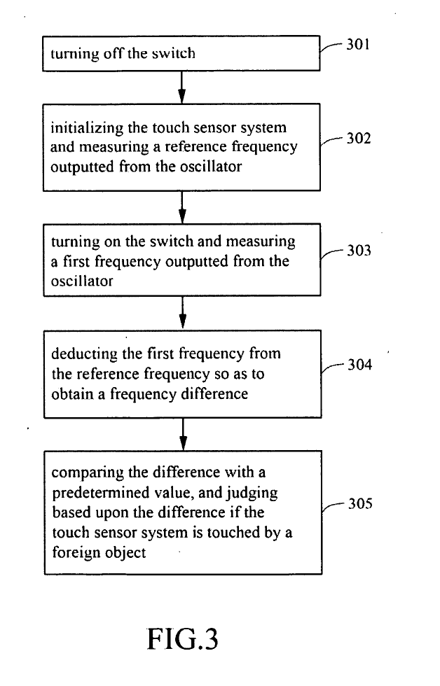

FIG. 3 illustrates a compensation method for a touch sensor system, where the touch sensor system comprises a oscillator coupled to an input pad outside the system via a switch, said method comprises the steps of: turning off the switch 301; initializing the touch sensor system and measuring a reference frequency outputted from the oscillator 302; turning on the switch and measuring a first frequency outputted from the oscillator 303; deducting the first frequency from the reference frequency so as to obtain a frequency difference 304; and comparing the difference with a predetermined value, and judging based upon the difference if the touch sensor system is touched by a foreign object 305.

Preferably, wherein said frequency can be replaced by a period.

Preferably, said method can be applied to eliminating an effect of temperature, humidity, process variation, and an operating voltage of the touch sensor system over the touch sensor system.

Preferably, said method can be done without an operating voltage calibration process.

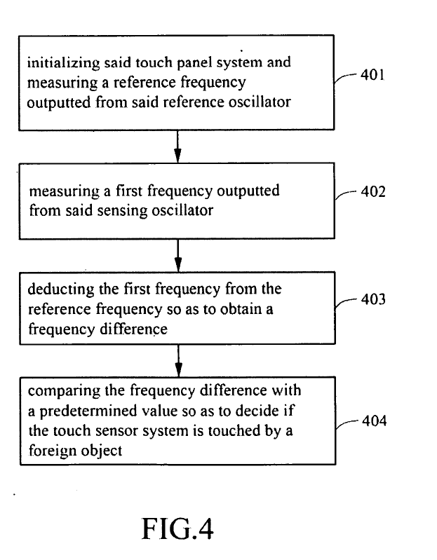

FIG. 4 illustrates a compensation method for a touch sensor system, said touch sensor system comprises an reference oscillator and a sensing oscillator, said compensation method comprising steps of: initializing said touch sensor system and measuring a reference frequency outputted from said reference oscillator 401; measuring a first frequency outputted from said sensing oscillator 402; deducting the first frequency from the reference frequency so as to obtain a frequency difference 403; and comparing the frequency difference with a predetermined value so as to decide if the touch sensor system is touched by a foreign object 404.

Preferably, wherein said frequency can be replaced by a period.

Preferably, said method can be applied to eliminating an effect of temperature, humidity, process variation, and an operating voltage of the touch sensor system over the touch sensor system.

Preferably, the sensing oscillator is interconnected to an input pad of the touch sensor system via at least one switch.

Preferably, said method can be done without an operating voltage calibration process.

One skilled in the ordinary art can also understand, based upon the disclosures of the present invention, that to access the reference frequency for the oscillator and to access the external sensing frequency can be done simultaneously or sequentially. And by the same oscillator, the reference frequency and the external sensing frequency (first frequency) can be generated, e.g., one or several switches are installed outside the oscillator, when the switches are all open circuited, a reference frequency thereof can be measured; and when any one of the switches is closed, then the external approaching can be sensed.

The invention being thus aforesaid, it will be obvious that the same may be varied in many ways. Such variations are not to be regarded as a departure from the spirit and scope of the invention, and all such modifications as would be obvious to one skilled in the art are intended to be included within the scope of the following claims.

We claim:

1. A compensation method for a touch sensor system, said touch sensor system comprises an oscillator connecting to a input pad outside the touch sensor system via a switch, said compensation method comprising steps of:
(a) turning off the switch;
(b) initializing the touch sensor system and measuring a reference frequency outputted from the oscillator;
(c) turning on the switch and measuring a first frequency outputted from the oscillator;
(d) deducting the first frequency from the reference frequency so as to obtain a frequency difference; and
(e) comparing the difference with a predetermined value, and judging based upon the difference if the touch sensor system is touched by a foreign object.

2. The method as recited in claim 1, wherein the aforementioned frequency can be substituted by a period.

3. The method as recited in claim 1, can be applied to eliminating an effect of temperature, humidity, process variation, and an operating voltage of the touch sensor system over the touch sensor system.

4. The method as recited in claim 1, can be done without an operating voltage calibration process.

5. A compensation method for a touch sensor system, said touch sensor system comprises an reference oscillator and a sensing oscillator, said compensation method comprising steps of:
(a) initializing said touch sensor system and measuring a reference frequency outputted from said reference oscillator;
(b) measuring a first frequency outputted from said sensing oscillator;
(c) deducting the first frequency from the reference frequency so as to obtain a frequency difference; and
(d) comparing the frequency difference with a predetermined value so as to decide if the touch sensor system is touched by a foreign object.

6. The method as recited in claim 1, wherein the aforementioned frequency can be substituted by a period.

7. The method as recited in claim 1, can be applied to eliminating an effect of temperature, humidity, process variation, and an operating voltage of the touch sensor system over the touch sensor system.

8. The method as recited in claim 1, can be done without an operating voltage calibration process.

9. The method as recited in claim 5, wherein said sensing oscillator is interconnected to an input pad of the touch sensor system via at least one switch.
